(19) United States
(12) Patent Application Publication
(10) Pub. No.: US 2008/0272394 A1
(43) Pub. Date: Nov. 6, 2008

(54) JUNCTION FIELD EFFECT TRANSISTORS IN GERMANIUM AND SILICON-GERMANIUM ALLOYS AND METHOD FOR MAKING AND USING

(76) Inventors: Ashok Kumar Kapoor, Palo Alto, CA (US); Madhukar B. Vora, Los Gatos, CA (US); Weimin Zhang, San Jose, CA (US); Sachin R. Sonkusale, Campbell, CA (US); Yujie Liu, Sunnyvale, CA (US)

Correspondence Address: PERKINS COIE LLP, P.O. BOX 1208, SEATTLE, WA, 98111-1208, US

(21) Appl. No.: 11/870,212

(22) Filed: Oct. 10, 2007

Related U.S. Application Data
(60) Provisional application No. 60/927,306, filed on May 1, 2007.

(51) Int. Cl. H01L 29/808; H01L 21/337; H01L 29/00

(52) U.S. Cl. 257/190; 257/268; 257/513; 438/196; 257/E21.446; 257/E29.312; 257/E29.001

(57) ABSTRACT

Junction field effect transistors (JFET) formed in substrates containing germanium. JFETs having polycrystalline semiconductor surface contacts with self-aligned silicide formed thereon and self-aligned source, drain and gate regions formed by thermal drive-in of impurities from surface contacts into the substrate, and implanted link regions. Others have a polycrystalline semiconductor gate surface contact and metal back gate, source and drain contacts and a metal surface contact to the gate surface contact with implanted source and drains and a self-aligned gate region. JFETs having a polycrystalline semiconductor gate surface contact and metal back gate, source and drain contacts and a metal surface contact to the gate surface contact with implanted source and drains and a self-aligned gate region and silicide formed on the top of the source, drain and back gate contacts and on top of the gate polycrystalline semiconductor gate contact to which the metal surface contacts make electrical contact.

### CROSS-REFERENCE TO RELATED APPLICATIONS

This application claims the benefit of priority under 35 USC 119 to U.S. Provisional Patent Application Ser. No. 60/927,306 filed May 1, 2007 and entitled “HIGH MOBILITY JFETS ON GERMANIUM-ON-SILICON OR INSULATOR SUBSTRATES”, which application is incorporated by reference.

### FIELD OF THE INVENTION

The present invention pertains generally to junction field effect transistors (JFETs) and methods for making and using such JFETs, and more particularly to structure and method for making and operating junction field effect transistors (JFETs) formed on a Germanium bearing layer for operation in a enhancement mode to achieve high-speed and low-power operation.

### BACKGROUND

Junction field effect transistors (JFETs) have the advantage of being able to solve numerous problems encountered in conventional CMOS integrated circuit fabrication which have arisen as a result of line-width decreasing below 100 nanometers and even more significantly for line-widths that have decreased below 65 nanometers.

While these silicon-based small JFETs have significant advantages over such conventional CMOS devices and electronic circuits incorporating such CMOS devices, there is always a need for smaller, faster, and more efficient semiconductor transistors and circuits incorporating such transistors.

It is known that pure germanium may typically provide higher electron and/or hole mobility than silicon. However, heretofore this known higher mobility in germanium over silicon has not been exploited in designing and manufacturing transistors.

There therefore remains desirability to take advantage of the higher electron and/or hole mobility of germanium as compared to silicon and to fabricate transistors and circuits comprising a plurality of transistors. Such germanium based transistors and circuits may be expected to perform better at high frequencies and high switching speeds than a silicon-based transistor as a result of the greater electron and/or hole mobility.

### BRIEF DESCRIPTION OF THE DRAWINGS

FIG. 1 is a diagram of the cross section of an embodiment of a metal contact enhancement mode JFET built in germanium or germanium-silicon alloy.

FIG. 2 is a diagram of the cross section of an embodiment of a metal contact enhancement mode JFET built in germanium or germanium-silicon alloy using spacers around the gate surface contact.

FIG. 3 is a diagram of the cross section of an embodiment of a polycrystalline semiconductor contact enhancement mode JFET built in germanium or germanium-silicon alloy with implanted link regions and self-aligned silicide formed on the tops of the surface contacts.

FIG. 4 is a cross-sectional view of an exemplary JFET built with triple-well reverse-biased PN junction isolation having source, gate and drain regions, which have been formed by ion implantation and which are not self-aligned.

FIG. 5 is a cross-sectional view of an exemplary JFET built with triple-well reverse-biased PN junction isolation structure and with self-aligned source, gate, drain regions, and back gate and well contacts.

### SUMMARY

In one aspect, embodiments of the invention provide a junction field effect transistor (JFET) device comprising: a semiconductor substrate including a first layer comprising silicon or an insulator, and a second layer comprising germanium or a germanium-silicon alloy; a source region formed in the substrate second layer; a drain region formed in the substrate second layer and spaced apart from the source region; a channel region formed in the substrate second layer between the source and drain regions; a gate region formed in the substrate second layer and abutting the channel region; an isolation structure formed in the substrate second layer and defining an active area within the substrate comprising a well region to isolate the source, drain, gate, and channel regions of the JFET from adjacent JFET devices formed within the substrate; and a back gate region formed in the substrate second layer and in contact with the well region. In another aspect, embodiments of the invention provide a method of making the junction field effect transistor (JFET) device.

In another aspect, embodiments of the invention provide a method for forming at least one of a source, a drain, and a gate region of a junction field effect transistor (JFET), the method comprising: forming a heavily doped region of polysilicon on a semiconductor substrate; using the heavily doped region of polysilicon as the source of dopant impurities to form the at least one of the source, drain and gate region by thermally driven diffusion of the dopant from the overlying dopant in the polysilicon layer into an underlying layer of the substrate; and using the heavily doped region of polysilicon for forming an ohmic contact with the at least one region to connect the at least one region to an external circuit. In another aspect, embodiments of the invention provide at least one of a source, a drain, and a gate region of a junction field effect transistor (JFET) formed according to embodiments of methods of the invention.

In still another aspect, embodiments of the invention provide a method for fabricating a germanium semiconductor bearing substrate junction field effect transistor (JFET), the method comprising: forming an active area defined by an isolation structure in a germanium bearing semiconductor substrate, the isolation structure including a doped well; forming a source region in the substrate; forming a drain region in the substrate spaced apart from the source region; forming a channel region in the substrate; forming a gate region in the substrate abutting the channel region; forming a drain region in the substrate spaced apart from the source region; and forming a back gate region in the substrate, the back gate region being in contact with the doped well. In yet another aspect, embodiments of the invention provide a germanium semiconductor bearing substrate junction field effect transistor (JFET) formed according to embodiments of the methods of the invention.

In still another aspect, embodiments of the invention provide an electronic circuit comprising: a plurality of semiconductor devices wherein at least one of the plurality of semiconductor device in the electronic circuit comprises a junction field effect transistor, the junction field effect transistor comprising: a semiconductor substrate including a first layer comprising silicon or an insulator, and a second layer comprising germanium or a germanium-silicon alloy; a source region formed in the substrate second layer; a drain region formed in the substrate second layer and spaced apart from the source region; a channel region formed in the substrate second layer between the source and drain regions; a gate region formed in the substrate second layer and abutting the channel region; an isolation structure formed in the substrate second layer and defining an active area within the substrate comprising a well region to isolate the source, drain, gate, and channel regions of the JFET from adjacent JFET devices formed within the substrate; and a back gate region formed in the substrate second layer and in contact with the well region. In still another aspect, embodiments of the invention provide a method of making the electronic circuit.

In yet another aspect, embodiments of the invention provide an isolation structure for use with a semiconductor transistor device formed in a multi-layer substrate including a germanium bearing layer and either an insulation layer or a silicon bearing layer, the isolation structure comprising: a trench formed in the germanium bearing layer of the semiconductor; the trench forming a cavity and the cavity having silicon nitride lining deposited thereon; and a silicon dioxide layer formed on the silicon nitride layer interior to the cavity and optionally filling the interior of the silicon nitride lined cavity.

In even another aspect, embodiments of the invention provide a method of making an isolation structure for use with a semiconductor transistor device formed in a multi-layer substrate including a germanium bearing layer.

In still another aspect, embodiments of the invention provide a method of using and operating junction field effect transistors and circuits incorporating such junction field effect transistors and substructures thereof.

### DETAILED DESCRIPTION OF THE VARIOUS EXEMPLARY EMBODIMENTS

Various non-limiting exemplary embodiments of the invention are now described relative to the drawings.

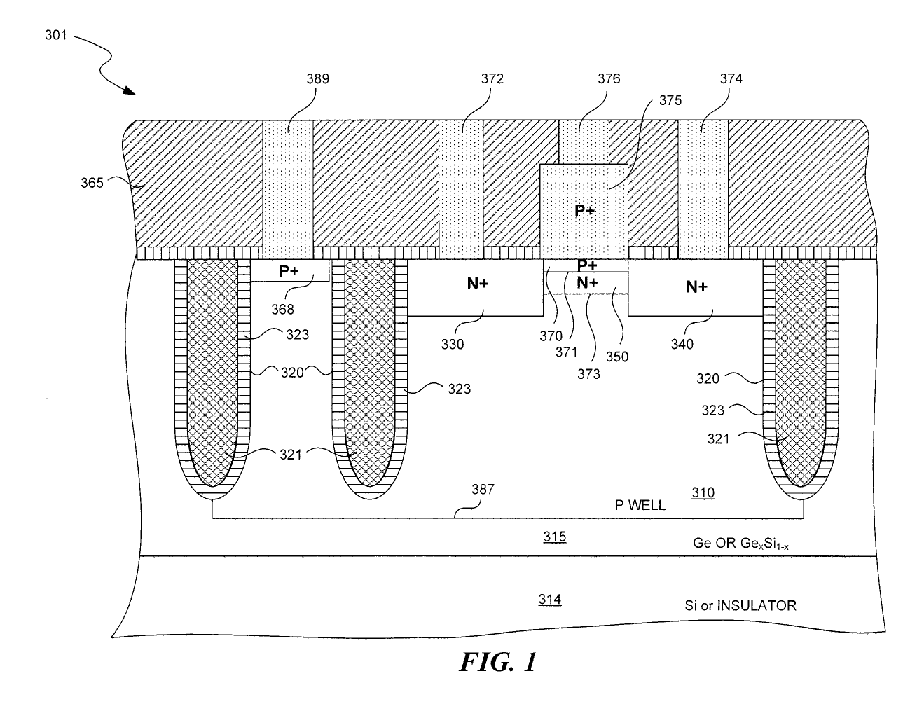

FIG. 1 shows a cross-sectional view of the structure of one embodiment of an enhancement mode n-channel JFET 301 built in a germanium bearing substrate, such as for example a germanium or germanium-silicon alloy substrate. The substrate in the embodiment of FIG. 1 includes a first layer 314 comprising silicon or a silicon alloy or an insulator, and a second layer 315 comprising a germanium bearing material, such as for example germanium or a germanium-silicon alloy. The JFET 301 further includes four regions; a source region 330, a gate region 370, a drain region 340, and a p-well region 310. The source and drain regions 330 and 340 may be formed by ion implantation or in other ways known in the art. The gate region 370 may advantageously be formed by a thermal drive in from the doped polycrystalline semiconductor gate surface contact 375 or in other ways known in the art. The JFET is formed in a germanium bearing region such as a region of germanium or germanium alloy 315 which may be formed on a pure or substantially pure silicon or insulator substrate as known in the art. In one non-limiting embodiment of the JFET, the semiconductor substrate layers 315 and 314 may be selected from the group comprising: a germanium containing layer; pure germanium; single crystal germanium grown in one or more layers on a single crystal silicon substrate; single crystal germanium grown in two or more layers on an insulating substrate; a silicon-germanium alloy grown on a single crystal silicon substrate; a silicon-germanium alloy grown in two or more layers on an insulating substrate, and a combination of any two or more of these.

The JFET is isolated from the surrounding semiconductor and for example other JFETs formed in the substrate by any isolation structure. The isolation structure may for example, be either Shallow Trench Isolation (STI) trenches, or multiple well (e.g., triple well) reversed biased PN junction isolation structures. In the non-limiting embodiments shown in FIG. 1-FIG. 3, the JFET active area is isolated from the surrounding devices by Shallow Trench Isolation (hereafter STI) trenches 320 lined with silicon nitride 323 and filled with silicon dioxide 321 which has been polished back so as to be flush with the top surface of the germanium or germanium alloy layer 315. The silicon nitride 323 is removed from over the active area after formation of the STI trenches 320.

The channel 350 between the source 330 and drain 340 is a doped region. For an n-channel JFET, the source 330 and drain 340 are highly doped n-type regions formed by doping the substrate with donor type impurities such as for example by phosphorous, arsenic or antimony. The p-well region 310 is doped by acceptor impurities, such as for example by boron or indium. The channel 350 is a narrow region which is doped n-type connecting source and drain.

The gate region 370 is a shallow p-type region formed within the channel 350, connecting source and drain, by methods such as diffusion of dopants from a heavily p+ doped polycrystalline semiconductor region 375. The depth of the gate-channel junction 371 (formed between the gate 370 and the channel 350), and the depth of the channel-well junction 373 (formed between the channel 350 and the p-well region 310), and the doping profiles of the gate 370 and the channel 350 and the p-well 310 are coordinated so as to achieve enhancement mode operation, that is substantially zero drain current at zero gate bias. Generally, this is achieved by making the gate region 370 doping and the p-well region 310 doping such that the depletion region below the gate-channel PN junction 371 at zero gate bias meets or touches the depletion region above the channel-well PN junction 373 at zero gate bias so as to pinch off the channel 350. Enhancement mode operation then has substantially zero current flow through the channel 350 at zero gate bias, and the current does not begin to flow in the channel until the pinch-off condition is removed or eliminated by changing the gate bias conditions. Embodiments that provide such doping profiles of the gate region, channel region and the well below the channel are controlled to achieve enhancement mode operation where the channel region is pinched off at substantially zero gate bias advantageously reduce static power consumption as compared to conventional structures and devices. Enhancement mode operation therefore reduces power consumption and solves the power consumption issues of CMOS structures and devices having small line widths as well as reducing power consumption as compared to other conventional transistor devices.

Contact to the source region 330 is via a metal surface contact 372. Contact to the drain region 340 is via a metal surface contact 374. Contact to the gate region is by doped polycrystalline semiconductor surface contact 375 having a metal gate surface contact 376 formed on top thereof. The gate surface contact 376 may be any conductive material compatible with the doped polycrystalline semiconductor 375.

Polycrystalline semiconductor surface contact 375 may comprises a region or slab of polysilicon which is doped heavily p-type and which may advantageously act as the source for doping of the gate 370 as described elsewhere herein. The p-type gate is used to control the conduction across the channel 350 from source 330 to drain 340. By this novel fabrication and construction technique, the gate 370 is diffused in the channel region from heavily doped polysilicon which also forms an ohmic contact with the gate. This allows the polysilicon to be used to connect the gate to the external circuit.

Contact to the back gate 368 may be via a metal back gate surface contact 389. In non-limiting embodiments, each of the metal surface contacts may advantageously but optionally have a barrier metal formed in the bottom of the contact hole to prevent the metal from spiking into the underlying structures and possibly destroying the underlying structures.

In non-limiting embodiments of the JFET structure, the gate surface contact 375 may be formed from a surface contact layer which is a single layer of polycrystalline silicon. Alternatively, it may be formed as a layer of polycrystalline germanium, or as an alloy of polycrystalline germanium and polycrystalline silicon, or in other ways. In embodiments, where the substrate layer 315 is germanium (Ge) or a germanium-silicon alloy (Geₓ Si₁₋ₓ), the surface contacts may be made of a first layer of polycrystalline silicon with a second layer of polycrystalline germanium or polycrystalline germanium-silicon alloy on top of the first layer. Other alternative embodiments may provide only a single layer of polycrystalline silicon without the second layer of polycrystalline germanium or polycrystalline germanium-silicon alloy on top of the first layer. The surface contact layer may be relatively thin, for example in non-limiting embodiments, the surface contact layer may typically be only about 500 angstroms thick or some thickness which has been scaled for the line widths of the controlling design rules for proper aspect ratio.

P-type conductivity enhancing impurities from the gate surface contact 375 are advantageously thermally driven into the underlying region by diffusion in a thermal drive-in step to form a self-aligned gate region 370. In non-limiting embodiments, the source region 330 and drain region 340 may be formed by n-type ion implantation, and the back gate ohmic contact 368 may be formed by p-type ion implantation. In the non-limiting JFET 301 embodiment of FIG. 1, the surface contact layer is formed by selective deposition or implantation of doped P+ over the area where gate region 370 and gate surface contact 375 are to be formed.

The region underneath the p-well back gate tap 368 may be doped heavily with p-type impurities to make good ohmic contact. The p-well 310 is formed in an n-well for applications where the p-well of the JFET has to be isolated. For applications where the p-well 310 is connected to the ground potential, the need for the n-well is obviated. Embodiments of the inventive structure and method include and cover both of these situations.

Ohmic contact to the p-well 310 may be formed by metal surface contact 389 which makes electrical contact with an ohmic contact in the form of a P+ region 368. The ohmic contact acts as the P-well contact by virtue of the configuration of the isolation trench regions 320. The isolation trenches 320 should not extend in depth below the depth of the P-well region 310 because such penetration into the well-substrate junction 387 (between the p-well region 310 and the germanium or germanium-silicon alloy substrate region 315) would cut off a conductive path from the ohmic contact 368 to the P-well region 310 under the channel region 350.

The channel 350 is a narrow region which is doped lightly N-type. In one non-limiting embodiment, the gate region 370 is a very shallow (for example, typically on the order of about 10 nanometers). P-type gate region 370 may be formed in the N-type channel 350 by methods known in the art, such as for example by diffusion of dopants from the overlying heavily P+ doped polysilicon gate surface 375, by ion implantation, or by other means or processes. In some non-limiting alternative embodiments, source and drain regions 330 and 340 may be formed by diffusion of n-type impurities into the underlying substrate.

The areas between the surface contacts 389, 372, 376, and 374 may typically be filled with a dielectric material 365 that has been planarized to the top surfaces of the surface contacts. In some non-limiting embodiments, this dielectric material may be a layer of nitride in contact with the germanium containing substrate (for example, in a germanium or germanium-silicon alloy) with a layer of silicon dioxide formed on top of the nitride. In non-limiting embodiments, typically a layer of silicon nitride or ONO (silicon dioxide-silicon nitride-silicon dioxide) is formed on top of the surface contacts to act as a polish stop layer during a polishing or planarization process. This polish stop layer stops the chemical-mechanical polishing (CMP) step typically used to planarize the dielectric material between the surface contacts at the top of the polish stop layer to form a planar surface needed for further lithography and processing.

In some non-limiting embodiments, the tops or upper surfaces of the surface contacts may advantageously have self-aligned metal silicide formed on top thereof by removing a silicon nitride layer formed on top of the surface contacts as a polish stop layer and replacing it with silicide.

The doping types are reversed for a p-channel JFET in relation to those described here for an n-channel JFET, that is, the p-type regions are replaced by n-type regions and vice versa. It should be pointed out that the doping the gate of the JFET with polycrystalline silicon 375 is maintained for a p-channel JFET as well. These changes as between p-channel and n-channel JFET devices pertain as well to the other JFET embodiments described herein elsewhere.

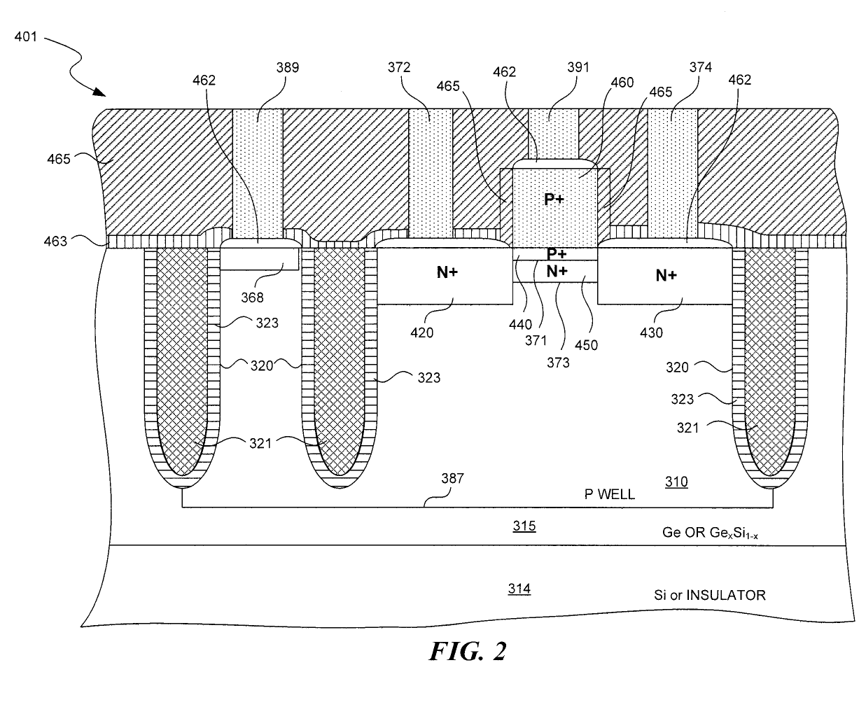

An alternative embodiment of an n-channel JFET structure 401 is shown in cross-section in FIG. 2. The n-channel JFET (as well as a corresponding p-channel JFET) uses a spacer dielectric structure 465 surrounding the gate surface contact 460. (This gate surface contact 460 corresponds substantially to the gate surface contact 375 in the JFET embodiment of FIG. 1 which does not include the spacer dielectric structure.) The structure of an exemplary n-channel JFET 401 is described here, it will be apparent to those skilled in the art in light of the description provided here that a p-channel JFET may alternatively be formed with appropriate changes in doping. The JFET 401 may be formed in a substrate such as that already described relative to the embodiment in FIG. 1. This substrate may for example, be comprised of a pure or substantially pure single crystal silicon (Si) or insulating layer 314 having a layer 315 containing germanium such as a layer of pure or substantially pure single crystal germanium or germanium-silicon alloy formed on layer 314.

The JFET 401 includes a p-well 310. As for JFET structure 301, the isolation for the JFET may be any known isolation structure, such as for example, isolation that is accomplished using Shallow Trench Isolation (STI) or reverse-biased PN junctions. In the non-limiting embodiment shown in FIG. 2, the isolation is advantageously provided by a Shallow Trench Isolation (STI) isolation trenches 320 filled with a dielectric material. The dielectric material may for example be silicon nitride 323 lining the walls of the trench 320 and some other dielectric material 321 such as for example silicon dioxide or other suitable material filling the isolation trench 320. The dielectric material is planarized to the top of the substrate 315.

The source region 420 and drain region 430 are formed as heavily doped N+ n-type regions. The channel region 450 between source and drain is a lightly doped N+ n-type region.

The gate region 440 is a doped p-type region. This doped P+ p-type gate region 440 may be diffused from the P+ polycrystalline semiconductor gate surface contact 460 with heavy p-type doping.

Insulating spacer region 465 is formed to surround the gate surface contact 460 which gate surface contact may be formed of polycrystalline semiconductor. The insulating spacer 465 may be a dielectric structure that for example includes or consists of a combination of silicon dioxide and silicon nitride layers. The source 420, drain 430, gate surface contact 460, and back gate 368 surface contacts 372, 374, 391, and 389 respectively, may advantageously be formed of metal.

In the exemplary embodiment of JFET 400 shown in FIG. 2, the top surfaces of the source and drain regions and back gate contact region 420, 430 and 368, respectively, and the top of the gate surface contact 460 may advantageously be covered with a highly conductive layer 462, such as for example by a highly conductive layer of one of the metallic compounds called silicides. The silicide layer 462 may advantageously be self-aligned to the back gate well tap 368, source 420, drain 430, and gate surface contact 460. This may be accomplished by forming the silicide only in the regions where there is exposed silicon or polycrystalline semiconductor.

One of the major functions of the insulating spacer dielectric structure 465 surrounding the gate surface contact is to electrically isolate the source 420 and drain 430 regions from the gate 440 region when the self-aligned suicides are formed over the source and drain regions to prevent the source and drain regions from being shorted to the gate surface contact. The insulating spacer dielectric structure 465 also facilitates efficient distribution of current from the contact inside the device.

The surface contacts to the well tap 368, source 420, drain 430, and gate regions 440 are marked as 389, 372, 374, and 391, respectively. Surface contacts 389, 372, 374, and 391 may all be formed of metal. Gate surface contact 460 may be a doped polycrystalline semiconductor.

The structure of the embodiment illustrated in FIG. 2 may be fabricated to operate in enhancement mode by controlling the depths of gate-channel junction 371 (formed between the gate 440 and the channel 450) channel-well junction 373 (formed between the channel 350 and the p-well region 310), and by controlling the doping of the gate region 440 and channel region 450 so as to achieve pinch off of channel region 450 at substantially zero gate bias voltage.

The regions between the surface contacts in the embodiment of FIG. 2 may be filled with planarized dielectric 465. As for the embodiment illustrated in and described relative to FIG. 1, this planarized dielectric layer may typically be a layer of silicon nitride in contact with the germanium bearing (e.g., germanium or germanium alloy) substrate layer 315 and with a layer of silicon dioxide on top of the silicon nitride layer. This dielectric layer is planarized down to be flush with the tops or upper surfaces of the polycrystalline surface contacts by chemical mechanical planarization or polishing (CMP).

It may be appreciated in light of the description provided here relative to exemplary JFET embodiments 301 (FIG. 1) and 401 (FIG. 2) that they differ primarily in that JFET 401 includes the insulating spacer 465, and may optionally though advantageously include the highly conductive layers 462. The use of highly conductive layers is not precluded in other embodiments. Analogous structures in JFET 401 not specifically described here are the same as for JFET 301.

Optionally the gate region 440 is of a lithographic minimum dimension. The silicide layer 462 overlaying a top surface of the gate electrode region 460, the gate electrode region 460, the gate region 440, and the channel region 450 have substantially the same length. The length difference of the gate region 440 and the channel region 450 between the source region 420 and the drain region 430 is formed from lateral diffusion of the source region 420 and the drain region 430, and lithographic misalignment does not contribute to the length difference. An insulating region marked 465 is inserted here, surrounding the gate, consisting of a combination of silicon dioxide and nitride layers.

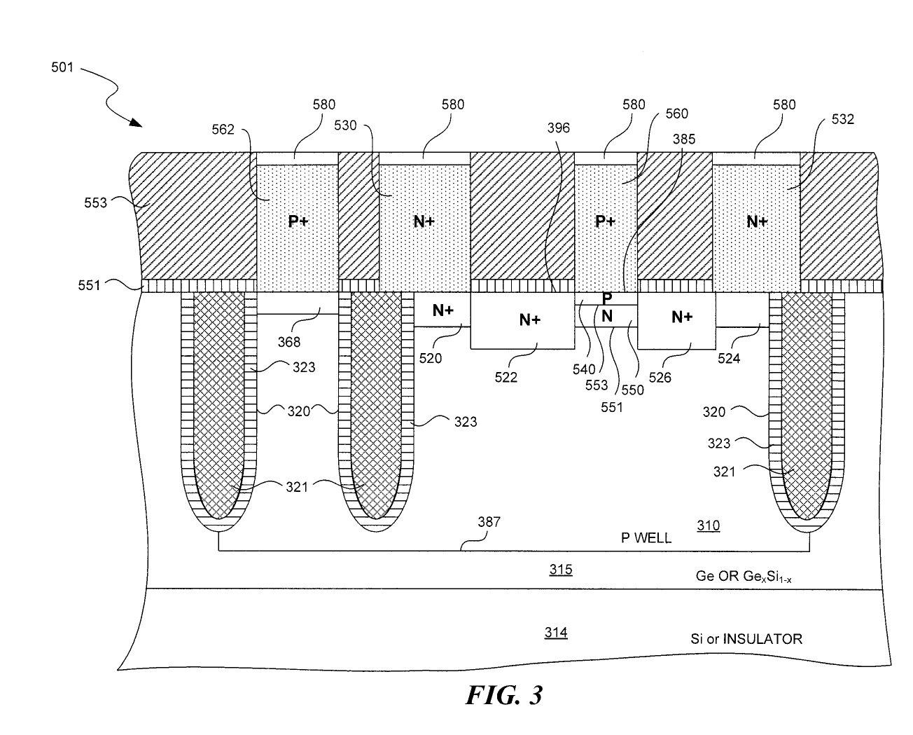

A second alternative embodiment of the JFET 501, shown in FIG. 3, includes a substrate comprised of a first layer 314 that may include single crystal silicon or insulator, and a second layer 315 containing germanium such as a pure or substantially pure single-crystal germanium or germanium-silicon alloy grown on layer 314.

In this non-limiting embodiment, surface contacts 530, 532, 560 and 562 to the source 520, drain 524, gate 540, and P-well 310 regions, are all made with doped polycrystalline semiconductor and advantageously but optionally have self-aligned silicide 580 formed on top of each surface contact. The spaces between the surface contacts may be filled with planarized dielectric material. Typically this dielectric material is comprised of a layer of silicon nitride 551 on top of the germanium bearing layer 315 and a layer of silicon dioxide 553 formed on top of the silicon nitride layer 551. The dielectric is then polished or planarized down to be flush with the top of a polish stop layer, typically silicon nitride, formed on top of the surface contacts. The polish stop layer may then be removed and replaced with silicide. The polycrystalline semiconductor surface contacts 530, 532, 560 and 562 to the source 520, drain 524, gate 540, and P-well 310 regions, respectively, may be made of polycrystalline silicon, polycrystalline silicon/germanium alloy, polycrystalline germanium, or the like. The polycrystalline material may be deposited on the germanium bearing layer without problems that may sometimes result from lattice mismatch since they are polycrystalline and not single crystal lattices.

The structure of JFET 501 shown and described relative to FIG. 3 has the desirable attribute of having contacts to all terminals or JFET regions (source, drain, gate, and p-well regions) at the same physical or topological level and having a planar top surface (the tops of the surface contacts and dielectric material between the surface contacts) upon which further lithography and processing may be performed. The structure of the JFET 501 of FIG. 3 has the further advantage that the silicide 580 is formed on top of the surface contacts and is not in contact with the top of the substrate 315.

There are several additional advantageous features of the embodiment of the JFET 501 shown in FIG. 3. First, the source 520 and drain 524 regions may be made much more shallow (shallower depth) than in conventional transistors, including shallower depth than conventional JFET transistors, because the source 520 and drain 524 surface contacts are not made by forming silicide directly on top of the substrate 315 over the source and drain regions. Instead, the source and drain contacts are formed by forming polycrystalline semiconductor surface contacts on the substrate surface 315 over the source 520 and drain 524 regions for the source 530 and drain contacts 532 and then forming self-aligned silicide 580 on the tops of these surface contacts. Because the silicide layer 580 is not directly in contact with the substrate 315, it does not penetrate down into the substrate during formation.

In conventional JFET transistors where the source and drain contacts are made by forming silicide directly on the surface of the substrate 315, the silicide is formed over the source 520 and drain 524 regions. When silicide is formed on a semiconductor surface in accordance with conventional practice, it goes down into the semiconductor a substantial distance. This forces the source and drain regions in conventional transistor structures to be made deeper than would generally be desired to prevent the silicide from punching all the way through the source and drain regions to the underlying p-well region. This forces the whole transistor structure to be made deeper, including to make the p-well 310 and the Shallow Trench Isolation (STI) trenches (when present) deeper. Deeper STI trenches are also necessarily wider isolation trenches, and such wider isolation trenches take up more semiconductor chip area, thereby making the whole JFET device area and total electronic circuit much larger than for a device made in accordance with the exemplary JFET embodiment in FIG. 3. Furthermore, the more shallow depth source and drain regions of the embodiments described herein improve short channel leakage properties as compared to conventional transistors.

In a semiconductor device, each transistor, including each JFET transistor, will consume or occupy some semiconductor chip area. In embodiments of the invention that do not have or need a dielectric spacer 465 formed on the sidewalls of the gate electrode 460 such as shown and described relative to FIG. 2, the size and area occupied by the JFET may be reduced relative to embodiments in which such dielectric spacer 465 is provided. It may be noted that the dielectric spacer formation may be accomplished by such processes as an anisotropic etch process. In non-limiting embodiments of the JFET, such as the embodiments shown and described relative to FIG. 1 and FIG. 3, the size (or dimensions) and spacing (or separation) of the source, gate, drain and surface contacts are determined photo-lithographically. This means that the size of the surface contacts and, significantly, the spacing or separation between the surface contacts is determined by a mask and an etch process and, therefore, both the surface contacts and the spaces between the surface contacts can have lateral dimensions which are the minimum feature size allowed by the design rules.

In the embodiments where photolithography is used to define the size and location and spacing of the surface contacts, the chip area per device is less because the spacing between surface contacts can be made less than the lateral thickness of the spacer dielectric structure which surrounds the gate surface contact.

In contrast, in the JFET transistors described for example relative to the JFET 401 shown in FIG. 2, the thickness of the dielectric spacer 465 on the sidewalls of the gate surface contact 460 are determined by the thickness of the polycrystalline material used to form the gate surface contact and the properties of the anisotropic etch used to remove horizontal components of the dielectric deposited over the gate surface contact. The thickness of the dielectric spacer in these JFET transistors having spacers 465 may be thicker than the minimum feature size for 65 nanometer, or less, design rules and smaller. This makes the overall transistor area greater in the JFET embodiments like those shown in and described relative to FIG. 2 than in the JFET embodiments such as those shown in and described relative to FIG. 1 and FIG. 3.

With further reference to FIG. 3, the source of JFET 501 may be formed by a combination of heavily n-doped regions 520 and 522. The drain of the JFET may also be formed by a combination of heavily doped n-type regions 524 and 526. Regions 522 and 526 are called the link regions, and are typically separately formed by ion implantation. The region 522 may be referred to as a source link region and the region 526 may be referred to as the drain link region because of their respective associations with the source and drain. The channel 550 is a shallow n-type doped region between drain and source. The p-type gate region 540 may be diffused in.

Source 530 and drain 532 surface contacts may be heavily N+ doped n-type polycrystalline semiconductor material. Typically, these polycrystalline semiconductor material structure may be pure polycrystalline silicon or they may be a layer of polycrystalline silicon in contact with the germanium bearing layer 315 with a second layer of polycrystalline germanium or polycrystalline germanium-silicon alloy on top of the first layer.

The source region 520 may be formed by diffusing n-type impurities from the source surface contact 530 into the germanium bearing substrate of the p-well 310. Similarly, drain region 524 may be formed by diffusion of n-type impurities from the drain surface contact 532 into the substrate. The source surface contact 530, drain surface contact 532, and gate surface contact 560 are advantageously in ohmic contact with source, drain and gate regions 520, 524, and 540, respectively.

Gate region 540 may be formed by diffusion of p-type impurities from the p-type gate surface contact 560 into the substrate.

Heavily doped link regions 522 and 526 connect the source and drain regions 520 and 524, respectively, to the channel 550 to form a highly conductive path from the source and drain to the channel to improve drain current. The link regions 522 and 526 may be formed by external doping, such as for example doping by ion implantation, plasma immersion implantation, or other similar doping methods or processes.

The well tap 368 may be formed by ohmic contact between the heavily p-doped polycrystalline semiconductor surface contact 562 and the p-type well region 310. The contacts to the JFET transistor are advantageously made at the top of the surface contacts 530, 532 and 560 and 562. In order to reduce ohmic contact resistance of these regions, self-aligned silicide 580 may be formed on top of the polysilicon layer. In a non-limiting alternate embodiment, contacts to the terminals of the transistor may be made directly to the polycrystalline surface contacts using metal contacts.

It may be appreciated in light of the description provided here, that in this or the other embodiments described herein may provide, form, or utilize any of various Germanium bearing substrates or substrate layers. By way of example, and not of limitation, the Germanium bearing layer or substrate by be selected from the following or combinations of these: (i) pure or substantially pure germanium; (ii) one or more pure germanium layers with the first layer of pure or substantially pure germanium epitaxially grown on a single crystal silicon substrate and any subsequent pure or substantially germanium layers epitaxially grown on the first layer after the first layer has been heat treated to reduce crystal defects, each subsequent epitaxially grown layer of pure or substantially germanium being heat treated to reduce crystal defects before any subsequent pure or substantially germanium layer is formed; (iii) single crystal pure or substantially pure germanium grown in one or more separately grown layers on an insulating substrate; (iv) one or more separately grown layers of silicon-germanium alloy with the first layer of silicon-germanium alloy epitaxially grown on a single crystal substrate where the amount of germanium can be anything from 1% up to 100% for each layer and wherein any second layer of silicon-germanium alloy is epitaxially grown on the first layer of silicon-germanium alloy after the first layer of silicon-germanium alloy has been heat treated to reduce crystal defects, and wherein each of any second or subsequent layers of silicon-germanium alloy is heat treated to reduce crystal defects before any subsequent layer of silicon-germanium alloy is grown thereon; (v) a silicon-germanium alloy grown in two or more layers on an insulating substrate, where the amount of germanium in each layer can be any amount from 1% up to 100% and wherein any second layer of silicon-germanium alloy is epitaxially grown on the first layer of silicon-germanium alloy after the first layer of silicon germanium alloy has been heat treated to reduce crystal defects, and wherein each of any second or subsequent layers of silicon-germanium alloy is heat treated to reduce crystal defects before any subsequent layer of silicon-germanium alloy is grown thereon; and (vi) combinations of any of the above.

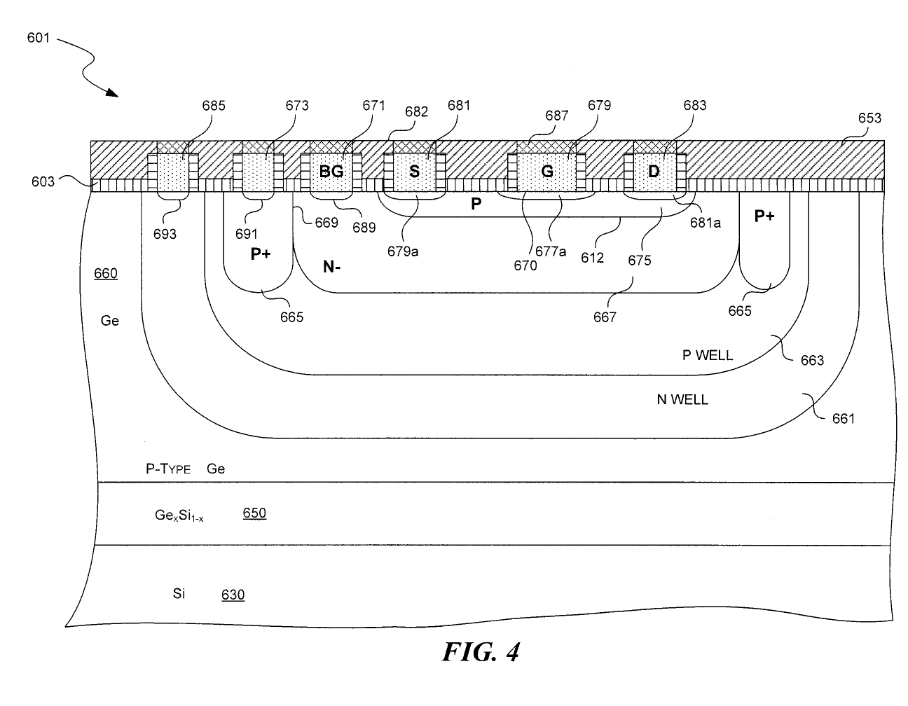

Another alternative embodiment of a structure and method isolating the active areas of complementary JFETs in the same substrate in a Germanium bearing layer may be accomplished using a multi-well reverse-biased PN-junction isolation structure and process. An exemplary but non-limiting embodiment of a process for forming a triple-well reverse biased junction isolated embodiment for a low-leakage JFET built in Germanium which is shown in FIG. 4 is now described. It may be appreciated that triple well isolation is only needed if doing complementary JFETs on the same substrate. Otherwise, when complementary JFET structures are not needed or desired on the same substrate, only a double well structure with for example, only an N-doped active area in Germanium bearing layer 660 surrounded by a P-well 663 and a P+ ring 665 surrounding the active area 667 and inside the P well is sufficient.

In a first step (Step 1), a P-doped Germanium layer is grown within a second Germanium bearing substrate layer on a first substrate layer 630 such as a silicon or insulator substrate.

Formation of the triple well isolation structure (Step 2) involves a number of substeps. First, first a deep N-well implant 661 process is performed, followed by a P-well implant 663 process step with energy set to contain the P-well 663 within the N-well 661. An active area N-implant 667 process is then performed to form the active area 667 within the P well 663 which will be electrically isolated by a reverse biased PN junction 669 in this non-limiting embodiment. This PN junction 669 may be formed by a P+ ring implant 665 to define the dimensions of the active area. The P+ implant 665 surrounds the active area 667 to provide higher dopant concentration at the surface than within the P-well implant 663. This P+ implant forms a PN junction 669 with the N-well 667 of the active area.

Surface contacts to all the afore described wells will be formed later so that suitable reverse bias voltages of the one or more PN junctions may be applied to electrically isolate the active area from adjoining active areas. In embodiments where poly level interconnects are to be formed, active areas where the channel implants are to be made may be masked off, and a layer of silicon nitride deposited over the entire wafer followed by a layer of silicon dioxide.

In operation, bias voltages are applied to P-well 665 and to the back gate contact 671 to reverse bias the PN junction 669 and electrically isolate the active area of N-well 667 from adjacent devices. The higher doping concentration of the P+ ring implant 665 as compared to the lighter doping of the N-active area 667 ensures that the depletion region surrounding the PN-junction 669 does not extend all the way across the P+ implant 665 to the N-well 661. Voltages applied to the N-well 667 and to the P-well 661 are controlled via surface contacts 671 and 673, respectively, to reverse bias PN-junction 669.

Next (Step 3), a P-type channel implant 675a process operation is performed to form the channel region 675.

An N-type gate implant 677 operation is performed (Step 4) to form the gate region 677a, and P-type implant operations (for a P-channel JFET) are performed to form source 679a and drain 681a regions, and implant the linking areas 612 between the source region and the channel under the gate and between the channel under the gate and the drain region to reduce the resistivity thereof, in the doped germanium bearing layer 660. The energy and dosage of all these implants are advantageously controlled to achieve the desired doping profile and JFET transistor characteristics (including the desired pinch-off voltage) such as for an enhancement mode JFET device with zero voltage gate-to-source pinch-off voltage. Optionally, one may etch down through the silicon dioxide layer over the field down to the silicon nitride layer to define the routes of poly level interconnect channels, if used.

In a next step (Step 5), surface contacts are formed by depositing a layer of Polycrystalline Germanium or Polycrystalline Germanium/Silicon alloy over the entire wafer and etching it using appropriate masks and etching process to form separate isolated surface contacts, including: gate contact 679, source contact 681, drain contact 683, back gate contact 671, and P+ well area surface contact 673.

In addition, separate masking and ion implantation steps (Step 6) may be used to dope the surface contacts 679, 681, 683, 671, and 673 with the appropriate polarity conductivity enhancing impurities. Source and drain surface contacts 681, 683 get doped one polarity, and gate and back gate surface contacts 679, 671 get doped the opposite polarity. In some embodiments, this process step may be performed before the forming of the surface contacts (See Step 5).

A layer 603 of Silicon Nitride may be deposited (Step 7) over the entire wafer to cover the tops and side walls of the surface contacts and the Germanium surface of the active area between the surface contacts and all field areas outside the boundaries of the active area.

A layer 683 of Silicon Dioxide may be deposited (Step 8a) over the entire wafer to fill the gaps between the surface contacts, and a chemical-mechanical-polish (CMP) step (Step 8b) may be performed to polish or planarize the Silicon Dioxide layer back to be flush with the top surface of the Silicon Nitride layer on top of the surface contacts.

Silicon Nitride that was formed (See Step 5) on the tops of surface contacts 679, 681, 683, 671, and 673 is then removed (Step 9).

In some non-limiting embodiments, a layer 687 of Titanium, Cobalt, Nickel Silicide or other material is advantageously but optionally formed on tops of each of surface contacts formed earlier (See Step 5) to reduce their resistivity (Step 10).

Finally, portions of the JFET structure 601 and other wafer portions may be insulated, and contact holes formed to the Polycrystalline Germanium or Polycrystalline Germanium/Silicon surface contacts, and interconnecting metal layer(s) formed and patterned to form desired circuit (Step 11). Multi-level metal processing (Step 12) may optionally be performed if desired, and the device structure passivated (Step 13).

In one non-limiting alternative embodiment, rather than using the process in Step 4 above for this JFET 601 embodiment, the gate region 677a (as well as the source region 679a and the drain region 681a) may be formed by impurities diffused by a thermal drive-in step into the channel region from an overlying heavily doped layer of Polycrystalline Germanium or Polycrystalline Silicon/Germanium alloy. This layer may be doped in the area overlying where the gate 677a is to be formed N-type (for a P-channel device), and it is doped P-type over the areas where the source and drain regions 679a and 681a, respectively, are to be formed. Likewise, other areas of the polycrystalline layer may be doped with appropriate impurities to form surface contacts with the correct conductivity type. The polycrystalline layer may then be used as a source of impurities during a high-temperature thermal drive in that causes impurities from the polycrystalline layer to enter the underlying doped Germanium bearing layer 660 to form the source 679a, gate 677a, and drain 681a regions and ohmic contacts 689, 691 and 693 under the surface contacts shown in the exemplary embodiment of FIG. 4. The polycrystalline layer is then etched to form separate gate contact 679, source contact 681, drain contact 683 and back gate contact 671 and P+ area surface contact 673.

Source and drain surface contacts 681 and 683 may be formed using doped Germanium Polycrystalline Germanium or Polycrystalline Germanium/Silicon alloy, or in some other manner. In some non-limiting embodiments, these surface contacts may be made with a refractory metal to prevent spiking, or the surface contacts may be formed with aluminum with a Titanium Silicide ohmic contact at the interface with the doped Germanium bearing layer 660 and a Titanium/Tungsten spiking barrier above the ohmic contact with aluminum above the spiking barrier.

N-well surface contact 685 may be used to control the substrate bias, and P-well surface contact 673 and back gate surface contact 671 may be used to reverse bias the PN junction 669.

The alternative processes described heretofore result in structures which may not have self-aligned source, gate and drain regions. In the embodiment of FIG. 4, the source implant 679a, the gate implant 677a, and the drain implant 681a should advantageously each be made wide enough to satisfy design rules. In other words, these implants should be wide enough so that the mask for etching the surface contacts for the source surface contact 682, gate surface contact 687, and drain surface contact 683, can be aligned properly so that these tiny contacts will be formed over the corresponding implants.

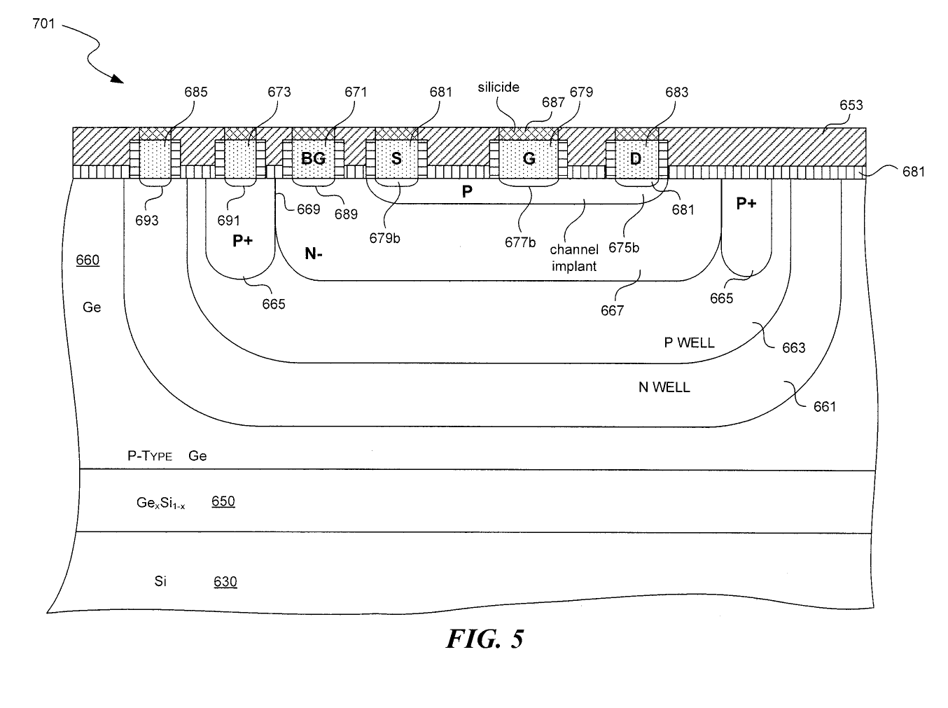

A further alternative non-limiting embodiment of a JFET having is now described relative to FIG. 5. Self-aligned source, drain and gate regions, and especially the gate region, are desirable to lower undesired parasitic gate capacitance which may in some instances somewhat slow down the operation of the transistor. Self-alignment is achieved in the device built according to a process by appropriately doping various regions of the polycrystalline layer from which the surface contacts are to be formed, etching it to form the surface contacts, and then driving in the impurities from the surface contacts into the underlying Germanium layer. One of the differences between the exemplary device of FIG. 5 and a device built according to some of the other processes describe here, such as relative to the structure and process described relative to FIG. 4, is that the isolation structure and the fact that the source and drain regions 279b and 281b are self-aligned by diffusion of impurities from the overlying polycrystalline surface contact into the Germanium substrate.

The device of FIG. 5 is isolated with the triple-well reverse biased PN junction isolation structure, but, in alternative embodiments, could be isolated with the STI trenches in Germanium described above.

An exemplary non-limiting process for forming a low-leakage JFET in a Germanium bearing substrate with self-aligned gate, source and drain regions using reverse biased PN junction isolation such as in the FIG. 5 embodiment is now described. It will be appreciated in light of the structure described herein, that the JFET structure may be built or formed in any way, and that the process described herein is an example of one way of forming such transistor. It will be apparent in light of the figures and description provided here, that a difference between the JFET 601 of FIG. 4 and the JFET 701 of FIG. 5 is the dimensions and overlap or spreading characteristics of source 679b, gate 677b, and channel region 675b between the two structures. In the FIG. 4 JFET embodiment these source 679a, gate 677a, and channel 675a regions are not self-aligned and extend laterally beyond their respective source, gate and drain surface contacts 681, 679, 683; whereas by comparison these source 679b, gate 677b, and channel 675b regions are self-aligned and may have smaller lateral dimensions than the regions under which they lie.

In a first step (Step 1), a P-doped Germanium layer 660 is formed within or on top of a germanium bearing layer 650 which is itself grown on top of a substrate such as silicon or insulator substrate layer 630. The Germanium layer 660 may be grown in any manner known in the art, and may for example by way of example but not of limitation be grown by a process such as described in U.S. Patent Publication 2006/0019466 A1, and independent of the process used may be first grown and annealed and then doped or it may be doped as it is grown.

Formation of the triple well isolation structure (Step 2) involves a number of substeps. First, first a deep N-well implant 661 process is performed, followed by a P-well implant 663 process step with energy set to contain the P-well 663 within the N-well 661. An active area N-implant 667 process is then performed to form the active area within the P well which will be electrically isolated by a reverse biased PN junction 669. This PN junction may be formed by a P+ ring implant 665 to define the dimensions of the active area. The P+ implant 665 surrounds the active area to provide higher dopant concentration at the surface than within the P-well implant 663. This P+ implant forms a PN junction 669 with the N-well 667 of the active area.

Next (Step 3), a P-type channel implant 675 process operation is performed to form the channel region 275b in each active area where a P-channel JFET is to be formed and implanting an N-type channel region in each active area where an N-channel JFET is to be formed.

A layer of Polycrystalline Germanium or Polycrystalline Silicon or Polycrystalline Germanium/Silicon alloy is deposited over the entire wafer (Step 4). This layer is then separately masked and heavily implanted with appropriate conductivity enhancing impurities in the regions where the source, drain, gate, back gate, P-well and N-well contacts are to be formed. This layer, as in other of the embodiments described herein, may be formed thinner than about 1000 angstroms, typically and advantageously about 500 angstroms thick, but these thicknesses are exemplary and are not limiting.

The polycrystalline layer is etched to form the separate surface contacts: N well 685, P well contact 673, back gate contact 671, source contact 681, gate contact 679, and drain contact 683 (Step 5).

Using the surface contacts as impurity sources, a high-temperature diffusion process may be performed to thermally drive impurities from each surface contact into the Germanium bearing layer 660 below the surface contact (Step 6). This forms a self-aligned source region 679b, a self-aligned drain region 681b, and a self-aligned gate region 677b, as well as self-aligned ohmic contacts 689, 691, and 693.

Link regions may optionally but advantageously be implanted between the source and gate, and between the gate and drain to lower the resistivity of these channel regions (Step 7).

A layer 608 of Silicon Nitride is deposited over the entire wafer to cover the tops and side walls of the surface contacts and the Germanium bearing region surface of the active area between the surface contacts (Step 8).

A layer 653 of Silicon Dioxide may be deposited over the entire wafer to fill the gaps between the surface contacts, and a chemical-mechanical-polish process may be performed to polish the Silicon Dioxide layer back to be flush with the top surface of the silicon nitride layer on top of the surface contacts (Step 9).

The silicon nitride is removed (Step 10) from the tops of surface contacts formed in the polycrystalline layer etch process (See Step 5).

A layer 687 of Titanium Silicide or other silicide may advantageously be formed on the tops of each of surface contacts formed in the polycrystalline layer etch process (See Step 5) to reduce their resistivity (Step 11).

Finally, portions of the structure may be Insulated, and contact holes formed to the Polycrystalline Germanium or Polycrystalline Germanium/Silicon surface contacts, and interconnecting metal layer(s) formed or deposited and patterned to form desired circuit (Step 12). Multi-level metal processing may optionally be performed if desired (Step 13), and the device structure passivated (Step 14).

Several alternative embodiments of JFETs have been described and it will be apparent that other variations and combinations of JFET device structures and methods and processes for making and using such JFETs and circuits incorporating such JFETs may be contemplated.

It may be appreciated that conventional semiconductor devices including CMOS devices continue to suffer from excessive power consumption, even as line widths shrink. Embodiments of the inventive JFETs provide at least one solution to this power consumption problem by providing a normally-off junction field effect transistor (JFET). Forming such normally-off junction field effect transistor (JFET) in a Germanium or Germanium bearing substrate has particular advantages as described.

The foregoing descriptions of specific embodiments and best mode of the present invention have been presented for purposes of illustration and description. They are not intended to be exhaustive or to limit the invention to the precise forms disclosed, and obviously many modifications and variations are possible in light of the above description and teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the claims appended hereto and their equivalents.

I/We claim:

1. A junction field effect transistor (JFET) device comprising:
a semiconductor substrate including a first layer comprising silicon or an insulator, and a second layer comprising germanium or a germanium-silicon alloy;
a source region formed in the substrate second layer;
a drain region formed in the substrate second layer and spaced apart from the source region;
a channel region formed in the substrate second layer between the source and drain regions;
a gate region formed in the substrate second layer and abutting the channel region;
a back gate region formed in the substrate second layer and in contact with the well region; and
an isolation structure formed in the substrate second layer and defining an active area within the substrate comprising a well region to isolate the source, drain, gate, back gate and channel regions of the JFET from adjacent devices formed within the substrate.

2. A junction field effect transistor as in claim 1, wherein the isolation structure comprises a shallow trench isolation (STI) structure.

3. A junction field effect transistor as in claim 2, wherein the shallow trench isolation (STI) structure comprises a silicon nitride lined cavity at least partially filled with silicon dioxide.

4. A junction field effect transistor as in claim 1, wherein the isolation structure comprises a reverse-biased PN-junction isolation structure including a PN-type implant surrounding the active area for reverse biasing the PN-junction in response to different voltages applied to the PN-type implant and to the back gate region.

5. A junction field effect transistor as in claim 1, further comprising:
a source region surface contact to the source region, a drain region surface contact to the drain region, a gate region surface contact to the gate region, and a well region surface contact to the well region.

6. The transistor of claim 5, wherein the source, drain, gate, and well surface contacts each being formed of a metal.

7. The transistor of claim 5, wherein the gate region surface contact comprising a polycrystalline semiconductor.

8. The transistor in claim 5, wherein the source, drain, gate, and well surface contacts each comprising doped polysilicon semiconductor material.

9. A junction field effect transistor as in claim 8, wherein each doped polysilicon semiconductor surface contact has a self-aligned silicide layer formed on top of the surface contact; and spaces between the surface contacts are filled with a dielectric material.

10. A junction field effect transistor as in claim 9, wherein the dielectric material filling the spaces comprises a layer of silicon nitride on top of the germanium bearing layer, and a layer of silicon dioxide formed on top of the silicon nitride layer.

11. A junction field effect transistor as in claim 5, further comprising a spacer dielectric structure surrounding the gate region surface contact.

12. A junction field effect transistor as in claim 11, wherein the spacer dielectric structure is formed of at least one of silicon nitride, silicon dioxide, and a combination of silicon nitride and silicon dioxide.

13. A junction field effect transistor as in claim 11, wherein the insulating spacer dielectric structure surrounding the gate surface contact is operable to electrically isolate the source and drain regions from the gate region when self-aligned silicides are formed over the source and drain regions to prevent the source and drain regions from being shorted to the gate surface contact.

14. A junction field effect transistor as in claim 1, further comprising: a top surface of the source region contact, a top surface of the drain region contact, a top surface of the back gate region contact, and a top surface of the gate region contact; and
the top surfaces of the source region contact, drain region contact, back gate region contact, and gate region contact are covered with a metallic silicide compound.

15. A junction field effect transistor as in claim 1, further comprising: doped link regions formed in the substrate second layer providing a conductivity enhanced electrical path from the source and the drain regions to said channel region.

16. A method for forming at least one of a source and a drain region of a junction field effect transistor (JFET), the method comprising:
forming a heavily doped region of polysilicon on a semiconductor substrate;
using the heavily doped region of polysilicon as the source of N/P-type dopant impurities to form the at least one of the source and drain regions as shallow junctions by thermally driven diffusion of the dopant from the overlying dopant in the polysilicon layer into an underlying layer of the substrate; and
using the heavily doped region of polysilicon for forming an ohmic contact with the at least one region to connect the at least one region to an external circuit.

17. A method as in claim 16, wherein the method further includes forming a gate region of the JFET and the gate regions is formed by a process comprising:
using the heavily doped region of polysilicon as the source of P/N-type dopant impurities to form the gate region as a shallow P/N-type region abutting a channel region connecting the source and drain regions by thermally driven diffusion of the dopant from the overlying dopant in the polysilicon layer into an underlying layer of the substrate;
the depth of a gate-channel junction formed between the gate and the channel and the depth of a channel-well junction formed between the channel and a p-well region, and the doping profiles of the gate and the channel and the p-well are coordinated so as to achieve enhancement mode operation, that is substantially zero drain current at zero gate bias; and
the enhancement mode operation being achieved by making the gate region doping and the p-well region doping such that the depletion region below a gate-channel PN-junction at zero gate bias touches the depletion region above the channel-well PN junction at zero gate bias so as to pinch off the channel.

18. A method for fabricating a germanium semiconductor bearing substrate junction field effect transistor (JFET), the method comprising:
forming an active area defined by an isolation structure in a germanium bearing semiconductor substrate, the isolation structure including a doped well in which a source region, a drain region, a channel region, a gate region, and a back gate region of the JFET are to be formed;
forming said source region in the doped well within the substrate;
forming said drain region in the doped well within the substrate spaced apart from the source region;
forming said channel region in the doped well within the substrate;
forming said gate region in the doped well within the substrate abutting the channel region; and
forming said back gate region in the substrate, said back gate region being in contact with the doped well.

19. A method for fabricating a junction field effect transistor as in claim 18, wherein the isolation structure is an isolation structure selected from the set of isolation structures consisting of:
an insulating material based isolation structure that includes a shallow trench isolation structure formed by (i) forming a trench, (ii) forming a layer of silicon nitride on walls of the trench, and (iii) thereafter filling an interior portion of the silicon nitride layer lined trench with silicon dioxide; and
a reverse-biased PN-junction isolation structure formed by a multiple-well process comprising enclosing the doped well by a second well comprising a PN-type implant, and enclosing the second well by a third well, the doped well, the PN-type implant and the third well each having and being electrically connected to a different respective surface contact.

20. A method for fabricating a junction field effect transistor as in claim 19, further comprising:
forming a source region surface contact to the source region, a drain region surface contact to the drain region, a gate region surface contact to the gate region, and a well region surface contact to the well region; and
forming a spacer dielectric structure to surround the gate region surface contact;
the gate region surface contact being formed of polycrystalline semiconductor; and
the spacer dielectric structure is formed of at least one of silicon nitride, silicon dioxide, and a combination of silicon nitride and silicon dioxide.

21. A method for fabricating a junction field effect transistor as in claim 18, further comprising:
forming a source region surface contact to the source region, a drain region surface contact to the drain region, a gate region surface contact to the gate region, and a well region surface contact to the well region, each the surface contact being formed of a metal; and
forming a metallic silicide compound layer on top surfaces of the source region, the drain region, and the back gate region.

22. A method for fabricating a junction field effect transistor as in claim 18, further comprising:
forming a source surface contact, a gate surface contact, a drain surface contact, and a well region surface contact, each the surface contact formed of doped polysilicon semiconductor; and
forming a metallic silicide compound layer on top surfaces of the source region contact, drain region contact, back gate region contact, and gate region contact.

23. A method for fabricating a junction field effect transistor as in claim 18, further comprising: forming doped link regions in the substrate providing a conductivity enhanced electrical path from the source and the drain regions, respectively, to the channel region.

24. An electronic circuit comprising:
a plurality of semiconductor devices wherein at least one of the plurality of semiconductor device in the electronic circuit comprises a junction field effect transistor, the junction field effect transistor comprising:
a semiconductor substrate including a first layer comprising silicon or an insulator, and a second layer comprising germanium or a germanium-silicon alloy;
a source region formed in the substrate second layer;
a drain region formed in the substrate second layer and spaced apart from the source region;
a channel region formed in the substrate second layer between the source and drain regions;
a gate region formed in the substrate second layer and abutting the channel region;
a back gate region formed in the substrate second layer and in contact with the well region; and
an isolation structure formed in the substrate second layer and defining an active area within the substrate comprising a well region to isolate the source, drain, gate, back gate and channel regions of the JFET from adjacent devices formed within the substrate

25. An isolation structure for use with a semiconductor transistor device formed in a multi-layer substrate including a germanium bearing layer and either an insulation layer or a silicon bearing layer, the isolation structure comprising:
a trench formed in the germanium bearing layer of the semiconductor;
the trench forming a cavity and the cavity having silicon nitride lining deposited thereon; and
a silicon dioxide layer formed on the silicon nitride layer interior to the cavity and optionally filling the interior of the silicon nitride lined cavity.
